(19) United States
(12) Patent Application Publication
(10) Pub. No.: US 2026/0088588 A1
(43) Pub. Date: Mar. 26, 2026

(54) Atomic Clock Device, Laser System, and Adjustment Method

(71) Applicant: SHIMADZU CORPORATION, Kyoto-shi (JP)

(72) Inventor: Yuya SAKAI, Kyoto-shi (JP)

(73) Assignee: SHIMADZU CORPORATION, Kyoto-shi (JP)

(21) Appl. No.: 19/331,888

(22) Filed: Sep. 17, 2025

(30) Foreign Application Priority Data
Sep. 20, 2024 (JP) 2024-164161

(51) Int. Cl. H01S 5/06; G04F 5/14; H01S 5/14; H03L 7/26

(52) U.S. Cl. CPC H01S 5/0612; G04F 5/14; H01S 5/14; H03L 7/26

(57) ABSTRACT

A laser device 10 includes an optical system comprising a laser diode 30 that emits laser light and an external resonator 50 provided outside the laser diode 30 that resonates the laser light emitted from the laser diode 30. The oscillation frequency of the laser light from the laser device 10 changes based on the current flowing through the laser diode 30 and the optical system including the laser diode 30 and the external resonator 50. An initial value of a parameter combination is set based on first data indicating a change in the oscillation frequency with respect to the parameter combination of a first parameter for adjusting the current and a second parameter for adjusting the optical system, and a predetermined target frequency.

### TECHNICAL FIELD

The present disclosure relates to an atomic clock device, a laser system, and an adjustment method.

### BACKGROUND ART

As a laser device, an external cavity diode laser (ECDL) is known, which includes a laser diode that emits laser light and an external resonator provided outside the laser diode that resonates the laser light emitted from the laser diode. The oscillation frequency of the laser light from the laser device can vary based on the current flowing through the laser diode and the distance between the laser diode and the external resonator.

For this reason, in the ECDL as described above, many parameters (hereinafter also referred to as "parameter combinations"), such as the current flowing through the laser diode and the resonance distance based on the resonance wavelength, are adjusted so that the laser light matches a predetermined target frequency. When the oscillation frequency of the laser light is adjusted based on the parameter combination, a mode hop, in which the oscillation frequency changes abruptly, may occur. A mode hop is a phenomenon in which, when the parameter combination is varied, the oscillation frequency of the laser light changes discontinuously at a certain parameter combination. Examples of parameters include the distance between the laser diode and the external resonator, or if the external resonator includes a lens, mirror, or dispersive element, the distance relationships or angles thereof.

The ECDL has a plurality of resonance structures therein, and the laser light oscillates at a wavelength at which the laser light simultaneously resonates in the plurality of resonance structures. Mode hopping has different dependencies on the parameter combinations for adjusting the plurality of resonance structures. For this reason, a mode hop may not occur even with a minute change in a parameter for a certain parameter combination, but may occur when a minute change is made based on another parameter combination. If one tries to avoid the occurrence of a mode hop when adjusting the oscillation frequency, the adjustment range of the oscillation frequency of the laser light is limited, making it difficult to appropriately adjust the oscillation frequency of the laser light. Therefore, in an ECDL, it is necessary to adjust the oscillation frequency of the laser light while avoiding mode hops. U.S. Patent No. 9,960,569 (Patent Literature 1) discloses an ECDL that adjusts the oscillation frequency of laser light while avoiding mode hops.

### CITATION LIST

### PATENT LITERATURE

[Patent Literature 1] U.S. Patent No. 9,960,569

### SUMMARY OF INVENTION

### TECHNICAL PROBLEM

U.S. Patent No. 9,960,569 discloses a technology for adjusting the oscillation frequency of laser light while avoiding mode hops by simultaneously adjusting the angle of a diffraction grating mounted inside the ECDL and the mirror position of the external resonator. However, in the technology disclosed in U.S. Patent No. 9,960,569, the user needs to accurately understand the internal structure of the ECDL to adjust the oscillation frequency. Furthermore, in the technology disclosed in U.S. Patent No. 9,960,569, it is also necessary to derive the adjustment conditions for the parameter combination for adjusting the plurality of resonance structures through complex calculations, so the applicable range was limited. Particularly in a laser system such as an atomic clock device that uses a plurality of laser devices, since there are individual differences in the resonance structure of each of the plurality of laser devices, the parameter combination cannot be made common among the plurality of laser devices. Therefore, with the conventional adjustment method, the oscillation frequency of the laser light cannot be adjusted appropriately, and in practice, the operator determined the parameters by trial and error.

The present disclosure has been made to solve such problems, and an object thereof is to provide a technology capable of appropriately adjusting the oscillation frequency of laser light emitted from a laser device.

### SOLUTION TO PROBLEM

An atomic clock device of the present disclosure includes a vacuum chamber, an atom generating device that irradiates an atomic beam into the vacuum chamber, a laser device that excites a transition between energy levels of atoms by irradiating laser light into the vacuum chamber in a state where the atomic beam is irradiated from the atom generating device, and a control device that controls the laser device. The laser device includes an optical system including a laser diode that emits laser light and an external resonator provided outside the laser diode that resonates the laser light emitted from the laser diode. The oscillation frequency of the laser light from the laser device changes based on the current flowing through the laser diode and the optical system including the laser diode and the external resonator. An initial value of a parameter combination is set based on first data indicating a change in the oscillation frequency with respect to the parameter combination of a first parameter for adjusting the current and a second parameter for adjusting the optical system, and a predetermined target frequency.

The present disclosure relates to a laser system for adjusting the oscillation frequency of laser light emitted from a laser device. The laser system includes the laser device and a control device that controls the laser device. The laser device includes an optical system including a laser diode that emits laser light and an external resonator provided outside the laser diode that resonates the laser light emitted from the laser diode. The oscillation frequency of the laser light from the laser device changes based on the current flowing through the laser diode and the optical system including the laser diode and the external resonator. The control device includes a step of acquiring first data indicating a change in the oscillation frequency with respect to a parameter combination of a first parameter for adjusting the current and a second parameter for adjusting the optical system, and a step of setting an initial value of the parameter combination based on the first data and a predetermined target frequency.

The present disclosure relates to an adjustment method for adjusting the oscillation frequency of laser light from a laser device by a computer. The laser device includes an optical system including a laser diode that emits laser light and an external resonator provided outside the laser diode that resonates the laser light emitted from the laser diode. The oscillation frequency of the laser light from the laser device changes based on the current flowing through the laser diode and the optical system including the laser diode and the external resonator. The processing executed by the computer includes a step of acquiring first data indicating a change in the oscillation frequency with respect to a parameter combination of a first parameter for adjusting the current and a second parameter for adjusting the optical system, and a step of setting an initial value of the parameter combination based on the first data and a predetermined target frequency.

### ADVANTAGEOUS EFFECTS OF INVENTION

According to the present disclosure, the oscillation frequency of the laser light emitted from the laser device can be appropriately adjusted. Therefore, for example, an initial value at which a mode hop is unlikely to occur even if a minute change in a parameter occurs can be set without trial and error by an operator.

### BRIEF DESCRIPTION OF DRAWINGS

FIG. 1 is a functional block diagram of an optical lattice clock according to Embodiment 1.

FIG. 2 is a conceptual diagram of an optical lattice.

FIG. 3 is a functional block diagram of a laser system according to Embodiment 1.

FIG. 4 is a schematic diagram for explaining a laser device according to Embodiment 1.

FIG. 5 is a diagram showing the relationship between the oscillation frequency of laser light and gain.

FIG. 6 is a diagram showing the relationship between the final oscillation frequency of laser light and gain.

FIG. 7 is a diagram showing the relationship between the temperature of a temperature control unit of the laser device and the difference from a target frequency.

FIG. 8 is a diagram showing the relationship between the combination of the current flowing through the laser diode and the temperature of the temperature control unit, and the frequency of the laser light.

FIG. 9 is a simplified diagram showing the combination of the current flowing through the laser diode and the temperature of the temperature control unit.

FIG. 10 is a diagram for explaining a case where the current flowing through the laser diode and the temperature of the temperature control unit are changed in the range from point C to point D.

FIG. 11 is a diagram showing the change in current and the change in temperature of the temperature control unit with respect to time in the laser device.

FIG. 12 is a diagram showing the change in the difference from the target frequency with respect to time of the laser light.

FIG. 13 is a flowchart showing the control content in the laser system.

FIG. 14 is a diagram showing the relationship between the combination of the current flowing through the laser diode and the temperature of the temperature control unit, and the frequency of the laser light, according to a modification.

FIG. 15 is a diagram showing the relationship between the combination of the current flowing through the laser diode and the temperature of the temperature control unit, and the oscillation state of the laser light, according to a modification.

FIG. 16 is a diagram showing the relationship between the combination of the current flowing through the laser diode and the temperature of the temperature control unit, and the light intensity of the laser light, according to a modification.

FIG. 17 is a diagram showing the relationship between the combination of the current flowing through the laser diode and the temperature of the temperature control unit, and a condition evaluation index, according to a modification.

FIG. 18 is a diagram showing the relationship between the combination of the current flowing through the laser diode and the temperature of the temperature control unit, and a condition evaluation index, according to a modification.

FIG. 19 is a schematic diagram for explaining a laser device according to Embodiment 2.

FIG. 20 is a schematic diagram for explaining a laser device according to Embodiment 3.

FIG. 21 is a schematic diagram for explaining a laser device according to Embodiment 4.

### DESCRIPTION OF EMBODIMENTS

The present embodiment will be described in detail with reference to the drawings. Note that the same or corresponding parts in the drawings are denoted by the same reference numerals, and a description thereof will not be repeated in principle.

### Embodiment 1

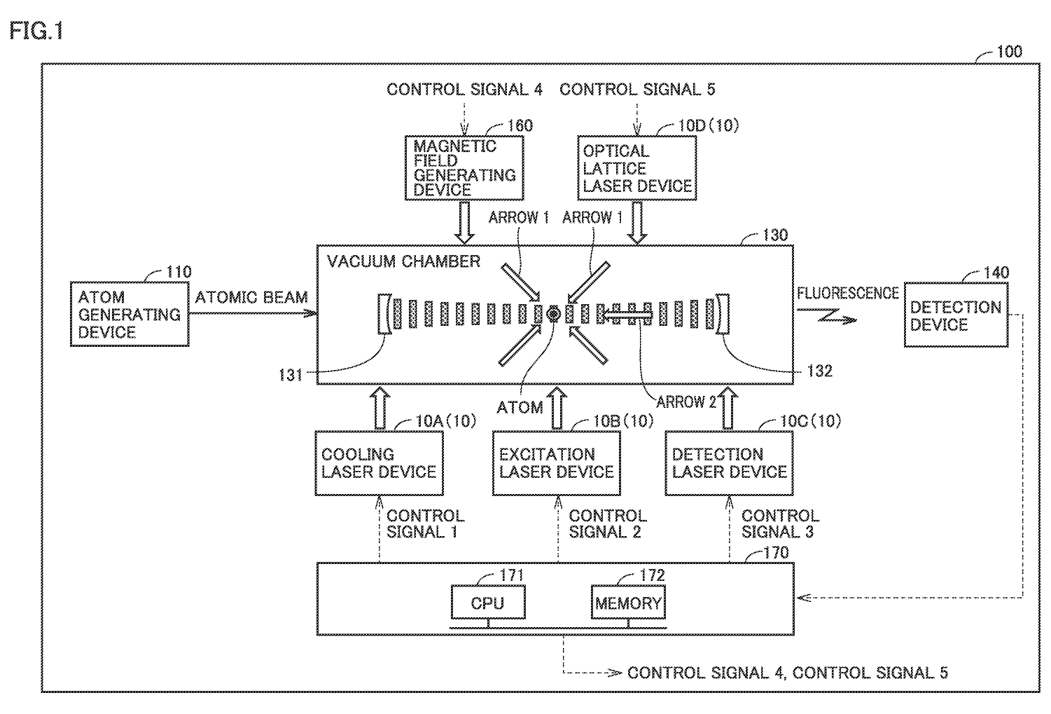

FIG. 1 is a functional block diagram of an atomic clock device 100 according to Embodiment 1. The atomic clock device 100 in FIG. 1 is an optical lattice atomic clock (also simply referred to as an "optical lattice clock").

Referring to FIG. 1, the atomic clock device 100 includes an atom generating device 110, a vacuum chamber 130, a detection device 140, a plurality of laser devices 10, a magnetic field generating device 160, and a control device 170. The plurality of laser devices 10 include a cooling laser device 10A, an excitation laser device 10B, a detection laser device 10C, and an optical lattice laser device 10D.

The atom generating device 110 includes a heating device (oven) (not shown) and heats a base material of atoms such as strontium, ytterbium, or mercury in the oven. By heating, chemical bonds between atoms are broken, whereby atoms are isolated and a group of atoms (atomic gas) is generated. The gasified atoms that have been heated have high kinetic energy, and thus a high-speed atomic gas is irradiated as an atomic beam from the atom generating device 110. The atomic beam irradiated from the atom generating device 110 is guided into the vacuum chamber 130.

The cooling laser device 10A is controlled by a control signal CTL1 from the control device 170. The cooling laser device 10A irradiates laser light (arrows AR1, AR2 in FIG. 1) that three-dimensionally opposes the atomic beam irradiated from the atom generating device 110 within the vacuum chamber 130. By irradiating this cooling laser light in the direction opposite to the movement direction of the atomic beam, the kinetic energy of the atoms is reduced (i.e., cooled), and as a result, the speed of the atoms is decreased.

Furthermore, a pair of opposing mirrors 131 and 132 are provided in the vacuum chamber 130. When laser light controlled to a specific wavelength (magic wavelength) by a control signal CTL5 of the control device 170 is irradiated from the optical lattice laser device 10D between the mirror 131 and the mirror 132, a standing wave is generated by the laser light between the mirror 131 and the mirror 132.

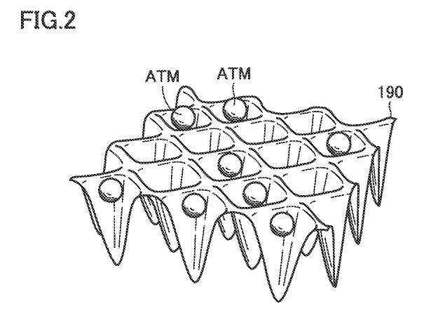

Generally, atoms polarize in an electric field and generate induced dipoles. These dipoles interact with the electric field. As a result, in a spatially non-uniform laser electric field, the electric potential for the atoms becomes minimal at the maximum points of the electric field strength, and the atoms are captured (trapped) at those positions. As described above, when a standing wave of laser light is generated between the mirror 131 and the mirror 132, the atoms are captured at the antinodes of the standing wave. By combining this standing wave three-dimensionally, an "optical lattice" in which atoms are arranged at half-wavelength intervals is realized. FIG. 2 conceptually shows an optical lattice. In FIG. 2, an optical lattice 190 generated by laser light is conceptually a spatial interference fringe in which depressions of electric potential are formed at regular intervals, and atoms ATM are captured in these depressions.

When an atom has momentum (velocity), the resonance frequency shifts due to the Doppler effect, which may degrade the accuracy of the measured time. By decelerating the atoms ATM in the atomic beam using the laser light of the cooling laser device 10A and capturing the atoms ATM using the optical lattice 190 as shown in FIG. 2, it becomes possible to search for the resonance frequency of the atoms in a stationary state.

The magnetic field generating device 160 is controlled by a control signal CTL4 from the control device 170 and applies a magnetic field to the moving atoms ATM by passing a current through an electromagnetic coil (not shown) arranged around the mirrors 131 and 132 in the vacuum chamber 130. The energy levels of the atoms ATM are controlled by this applied magnetic field, which contributes to various types of atomic cooling.

The excitation laser device 10B is controlled by a control signal CTL2 from the control device 170. The excitation laser device 10B irradiates the captured atoms ATM with pulsed laser light to excite the energy transition of the atoms ATM. Atoms generally have a plurality of specific energy levels, and in a transition between two different energy levels, they have the property of selectively absorbing photons with a frequency corresponding to the energy level difference.

The detection laser device 10C is controlled by a control signal CTL3 from the control device 170. The detection laser device 10C irradiates the atoms ATM with detection laser light after the excitation of the energy levels of the atoms ATM by the excitation laser device 10B. The laser irradiated from the detection laser device 10C generates fluorescence having an intensity proportional to the energy transition probability of the atom.

The detection device 140 receives the fluorescence generated by the detection laser device 10C and detects the intensity of the received fluorescence. The detection device 140 outputs a transition probability spectrum, which is represented by the detected fluorescence intensity and depends on the excitation laser frequency, to the control device 170.

The control device 170 includes, for example, a CPU (Central Processing Unit) 171 and a memory 172. The CPU 171 executes a program stored in the memory 172 to comprehensively control each device of the atomic clock device 100. The control device 170 specifies the resonance frequency of the atoms ATM from the transition probability spectrum received from the detection device 140. Furthermore, the control device 170 stabilizes the frequency of the laser light irradiated from the excitation laser device 10B based on the resonance frequency obtained by calculation.

In such an atomic clock device 100 including an optical lattice clock, an external cavity diode laser (ECDL), which includes a laser diode that emits laser light and an external resonator provided outside the laser diode that resonates the laser light emitted from the laser diode, is sometimes used as the laser device 10. In an ECDL, a mode hop, in which the oscillation frequency of the laser light changes abruptly, may occur. However, if a mode hop occurs when adjusting the oscillation frequency, it becomes difficult to appropriately adjust the oscillation frequency of the laser light. Therefore, in an ECDL, it is necessary to adjust the oscillation frequency of the laser light while avoiding mode hops.

Particularly in a laser system such as an atomic clock device that uses a plurality of laser devices, since there are individual differences in the resonance structure of each of the plurality of laser devices, the parameter combination cannot be made common among the plurality of laser devices. Hereinafter, an atomic clock device, a laser system, and an adjustment method capable of appropriately adjusting the oscillation frequency of laser light when an ECDL is applied to the laser device 10 will be described.

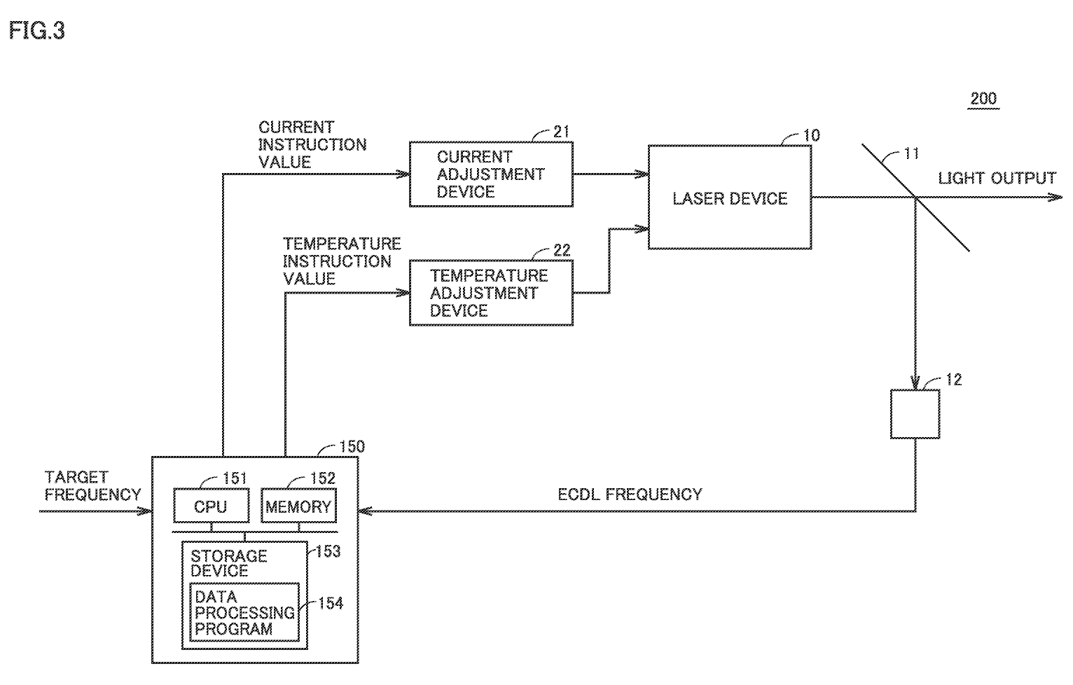

FIG. 3 is a functional block diagram of a laser system 200 according to Embodiment 1. The laser system 200 includes a laser device 10, a splitter 11, a photosensor 12, a control device 150, a current adjustment device 21, and a temperature adjustment device 22. The laser device 10 is, for example, an ECDL. Note that the laser device 10 may be another laser device different from an ECDL.

The laser device 10 emits (outputs) laser light when a current flows through a laser diode. The splitter 11 splits the laser light emitted from the laser device 10. The photosensor 12 converts the laser light split by the splitter 11 into an electrical signal and outputs information about various laser light parameters, such as the oscillation frequency of the ECDL, to the control device 150.

The control device 150 includes a CPU 151, a memory 152, and a storage device 153. The CPU 151 executes a program stored in the memory 152 to comprehensively control each device of the laser system 200. The CPU 151 (control device 150) executes arithmetic processing as the computer of the present disclosure. The CPU 151 can also be read as processing circuitry, in which processing is predefined by computer-readable code and/or hard-wired circuits. The memory 152 includes a storage area (for example, a working area) that stores program codes or work memory when the CPU 151 executes various programs. Examples of the memory 152 include volatile memories such as DRAM and SRAM, or non-volatile memories such as ROM and flash memory.

The storage device 153 stores various programs or various data executed by the CPU 151. The storage device 153 may be one or more non-transitory computer-readable media or one or more computer-readable storage media. Examples of the storage device 153 include an HDD (Hard Disk Drive) and an SSD (Solid State Drive). The storage device 153 according to the embodiment stores a data processing program 154 for executing data processing in which the CPU 151 processes detection data acquired from the photosensor 12.

The CPU 151, for example, receives a signal related to the oscillation frequency of the laser light from the laser device 10 from the photosensor 12 and executes processing to bring the oscillation frequency of the laser light closer to a predetermined target frequency. The target frequency is received by the control device 150 via an input/output interface (not shown).

The current adjustment device 21 varies the current flowing through the laser device 10 (the current flowing through a laser diode 30 described later) based on a current instruction value transmitted from the control device 150. The temperature adjustment device 22 varies the temperature of a temperature element of the laser device 10, which will be described later, based on a temperature instruction value transmitted from the control device 150.

An example of the structure of an ECDL will be described with reference to FIG. 4. FIG. 4 is a schematic diagram for explaining the laser device 10 according to Embodiment 1. The laser device 10 includes a laser diode 30, a lens unit 40, an external resonator 50, a mounting part 60, and a temperature control unit 70.

The laser diode 30 is composed of a P-type clad layer 31, an active layer 32, an N-type clad layer 33, and the like. In the laser diode 30, when electricity flows such that the P-type clad layer 31 is positive and the N-type clad layer 33 is negative, light is generated in the active layer 32. The inner end face of the active layer 32 functions as a light reflection surface. The light that is repeatedly reflected and amplified within the active layer 32 is emitted as laser light toward the lens unit 40.

The laser light emitted from the laser diode 30 is collected by a lens 41 arranged in the lens unit 40 so that each ray becomes parallel, and enters the external resonator 50. The external resonator 50 functions as a circuit grating that resonates the laser light by returning light of a specific wavelength among the incident laser light to the laser diode 30 as diffracted light. The resonated laser light is partially output to the outside.

In FIG. 4, a volume holographic grating (VHG) is shown as the circuit grating, but it may be a reflection type, a transmission type, or the like, and the circuit grating may have any structure. The laser diode 30 is mounted on the mounting part 60 via a pedestal part 36. The external resonator 50 is mounted on the mounting part 60 via a pedestal part 51. The temperature control unit 70 is in contact with the lower surface of the mounting part 60 and heats or cools the mounting part 60 from the lower surface. The temperature control unit 70 is, for example, a Peltier element that functions as a temperature element. When the mounting part 60 is heated or cooled by the temperature control unit 70, the mounting part 60 expands or contracts in the irradiation direction of the laser light. The mounting part 60 is, for example, made of a metal that expands or contracts when heated or cooled. As the mounting part 60 expands or contracts, the distance between the pedestal part 36 and the pedestal part 51 mounted on the mounting part 60 changes. Similarly, the distance between the pedestal part 36 and the lens unit 40, and the distance between the lens unit 40 and the pedestal part 51 change.

In this way, the optical system including the laser diode 30 and the external resonator 50 changes as the mounting part 60 is temperature-controlled by the temperature control unit 70. In other words, the temperature control unit 70 has a function of moving the external resonator 50 relative to the laser diode 30 by temperature change. Note that a piezoelectric element that expands and contracts according to a change in voltage may be used instead of the temperature element. In such a case, the piezoelectric element may be directly attached to the lower surface of the pedestal part so that the pedestal part 51 expands and contracts in the irradiation direction of the laser light. In this way, the distance between the laser diode 30 and the external resonator 50 can be adjusted by adjusting the voltage applied to the piezoelectric element. Furthermore, the present disclosure is not limited to this embodiment, and when the optical system includes a condensing element such as a mirror, the optical system may be adjusted by changing the mirror angle with a motor element.

Next, the gain characteristics of the laser light will be described. FIG. 5 is a diagram showing the relationship between the oscillation frequency of the laser light and the gain. The horizontal axis of FIG. 5 indicates the oscillation frequency of the laser light, and the vertical axis of FIG. 5 indicates the gain of the laser light. The laser device 10 has gain characteristics of a plurality of factors therein, and has a characteristic of oscillating at a frequency at which the composite gain, which is the product of the plurality of gain characteristics, is the highest.

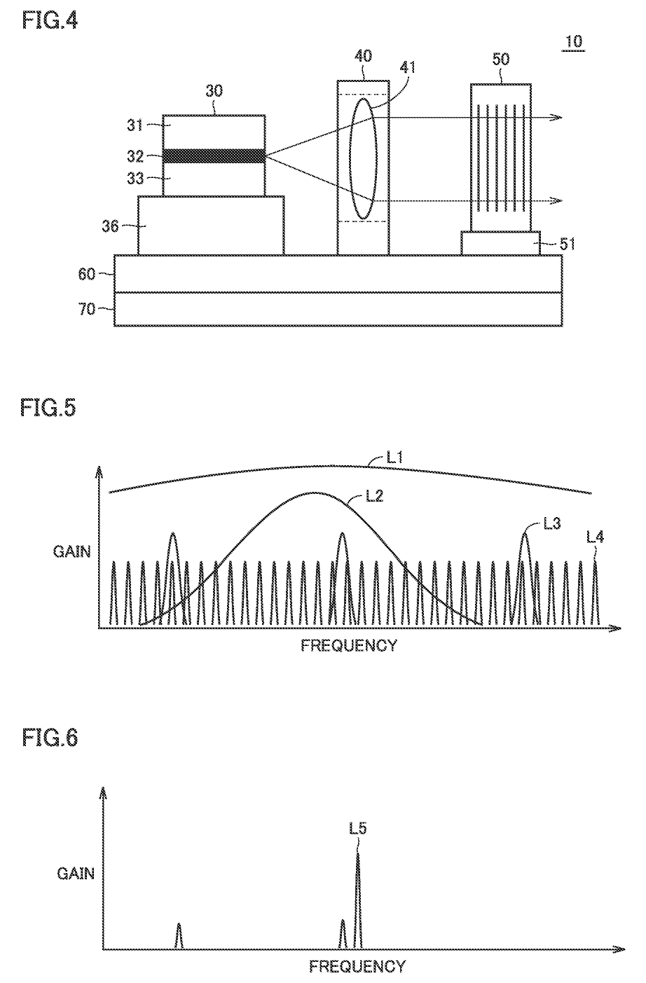

The gain characteristic L1 in FIG. 5 is a gain characteristic due to the material of the laser diode 30. The gain characteristic L2 in FIG. 5 is a gain characteristic due to the wavelength selectivity that reflects a specific wavelength on the reflection surface. The gain characteristic L3 in FIG. 5 is a gain characteristic due to resonance within the diode. The gain characteristic L4 in FIG. 5 is a gain characteristic due to the resonance structure of the external resonator. FIG. 6 shows the composite gain obtained by taking the product of the plurality of gain characteristics in FIG. 5. FIG. 6 is a diagram showing the relationship between the final oscillation frequency of the laser light and the gain. As shown in FIG. 6, the composite gain L5 becomes the final oscillation frequency of the laser light.

When adjusting the oscillation frequency of an ECDL, it is difficult to adjust the oscillation frequency because it is necessary to consider the influence of other gain characteristics in addition to changing the resonance frequency of the external resonator. Furthermore, in an ECDL, a mode hop, in which the oscillation frequency of the laser light changes abruptly, may occur. Mode hopping will be described with reference to FIG. 7.

FIG. 7 is a diagram showing the relationship between the temperature of the temperature control unit 70 of the laser device 10 and the difference from a target frequency. To observe the occurrence of a mode hop with respect to a target frequency, it is necessary to evaluate the correspondence between the target frequency and the parameters constituting the optical system. In this embodiment, as shown in FIG. 4, the parameter for adjusting the optical system is most predominantly the distance between the pedestal part 36 and the pedestal part 51. For a more rigorous evaluation, it is necessary to also evaluate the distance between the pedestal part 36 and the lens unit 40, and the distance between the lens unit 40 and the pedestal part 51 as parameters. It is optimal to observe the change in laser frequency when each of these distances is changed.

However, in this embodiment, it is considered that these distances can be represented by the degree of expansion and contraction of the mounting part 60, and furthermore, since the degree of expansion and contraction is a change due to the temperature of the mounting part 60, the temperature is used as a substitute parameter for these distances. In this way, even when there are a plurality of parameters that should originally be observed, if they are distances, heat can be used as a substitute parameter, and evaluation becomes easy. Although the temperature of the mounting part 60 may have a thermal effect on the laser diode 30, in this embodiment, since the change in laser frequency due to heat is observed, the change in the optical system and the thermal effect on the laser element are observed simultaneously.

The horizontal axis of FIG. 7 indicates the temperature of the temperature control unit 70 of the laser device 10, and the vertical axis of FIG. 7 indicates the difference between the oscillation frequency of the laser light from the laser device 10 and a target frequency. Due to the temperature change of the temperature control unit 70, the distance between the laser diode 30 and the external resonator 50 changes. As shown in FIG. 7, there is a region where the difference between the oscillation frequency and the target frequency changes continuously and proportionally to the temperature change of the temperature control unit 70, and a region where the difference between the oscillation frequency and the target frequency instantaneously discretizes without being proportional to the temperature change of the temperature control unit 70.

The region where the difference between the oscillation frequency and the target frequency changes continuously and proportionally is a region where, as the distance between the laser diode 30 and the external resonator 50 changes, the difference between the oscillation frequency and the target frequency changes in proportion to the change in the distance. On the other hand, the region where the difference between the oscillation frequency and the target frequency instantaneously discretizes without being proportional is a region representing that the product of all gain characteristics of the ECDL has moved to another resonance frequency that is one or more steps away due to gain characteristics other than the gain characteristic of the external resonator. In this way, a mode hop occurs in the region where the difference between the oscillation frequency and the target frequency instantaneously discretizes without being proportional.

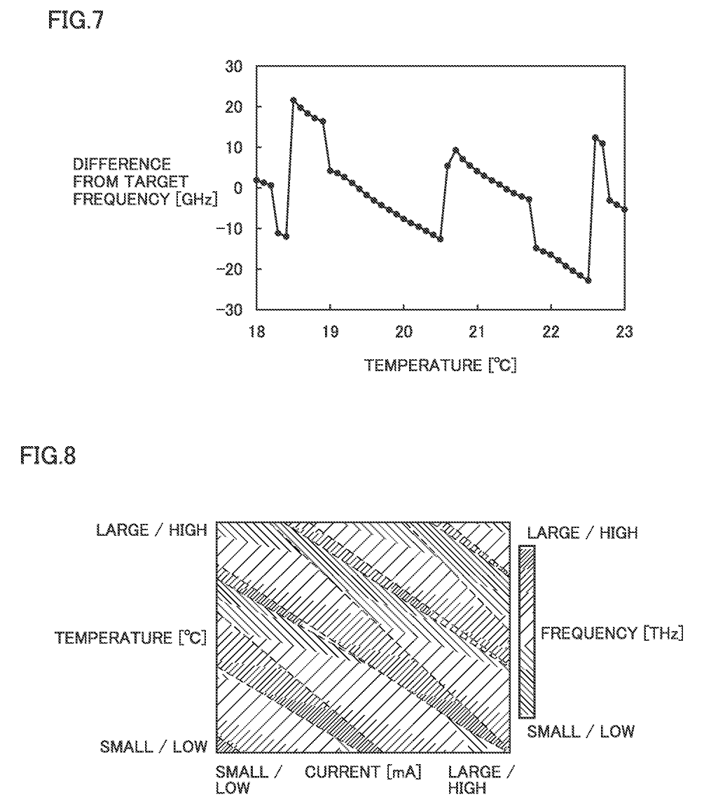

FIG. 8 is a diagram showing the relationship between the combination of the current flowing through the laser diode 30 and the temperature of the temperature control unit 70, and the frequency of the laser light. The temperature of the temperature control unit 70 is the same as the temperature when it is indirectly conducted to the external resonator 50. The horizontal axis of FIG. 8 indicates the current flowing through the laser diode 30, the vertical axis of FIG. 8 indicates the temperature of the temperature control unit 70, and the various diagonal lines in FIG. 8 indicate the oscillation frequency of the laser diode 30.

The oscillation frequency of the laser light from the laser device 10 changes based on a first parameter related to the current flowing through the laser diode 30 and a second parameter related to the optical system including the laser diode 30 and the external resonator 50. Therefore, to adjust the oscillation frequency of the laser light, it is necessary to adjust a parameter combination consisting of the first parameter and the second parameter so as to achieve a predetermined target frequency. In this embodiment, the temperature of the mounting part 60, which represents the relationship between the distances of the laser diode 30, the lens unit 40, and the external resonator 50 included in the optical system as a substitute, is used as the second parameter.

As shown in FIG. 3, in the laser system 200 according to Embodiment 1, the current adjustment device 21 is controlled based on a current instruction value transmitted from the CPU 151 (control device 150) to vary the current flowing through the laser device 10 (the current flowing through the laser diode 30) between a lower limit value and an upper limit value. Furthermore, in the laser system 200, the temperature adjustment device 22 is controlled based on a temperature instruction value transmitted from the CPU 151 (control device 150) to vary the temperature of the temperature control unit 70 between a lower limit value and an upper limit value. With such adjustment, the laser system 200 brings the oscillation frequency of the laser light closer to the target frequency. The laser system 200 can appropriately adjust the oscillation frequency of the laser light of the laser device 10 by performing such adjustment before the shipment of the laser device 10.

In FIG. 8, a change in the oscillation frequency with respect to a parameter combination of a first parameter for adjusting the current flowing through the laser diode 30 and a second parameter for adjusting the distance between the laser diode 30 and the external resonator 50, which changes with the temperature of the temperature control unit 70, is shown as first data. For example, when the first data is visualized as shown in FIG. 8, a two-dimensional table extracted in a matrix by setting a maximum and a minimum for the parameter related to current and the parameter related to temperature is created, and the measured value of the oscillation frequency for each parameter combination is associated with the two-dimensional table, thereby creating three-dimensional mapping data.

Note that since the optical system including the laser diode 30 and the external resonator 50 is greatly affected by individual differences, it is often not possible to apply the analysis results of a pre-prepared optical model. Therefore, in the present disclosure, for each laser device 10, information represented by FIG. 8 is acquired by a preliminary analysis that scans the first parameter and the second parameter. This preliminary analysis may be performed at least once before the device is completed, but may also be performed each time the device environment changes, such as after installation.

In the laser system 200, the first data indicating the change in the oscillation frequency with respect to the parameter combination is stored in the memory 152. The control device 150 extracts the boundary where a mode hop, in which the oscillation frequency of the laser light changes abruptly, occurs, using image processing or the like, based on such first data. For example, a plurality of broken lines indicated by broken lines in FIG. 8 are extracted as boundaries where a mode hop occurs.

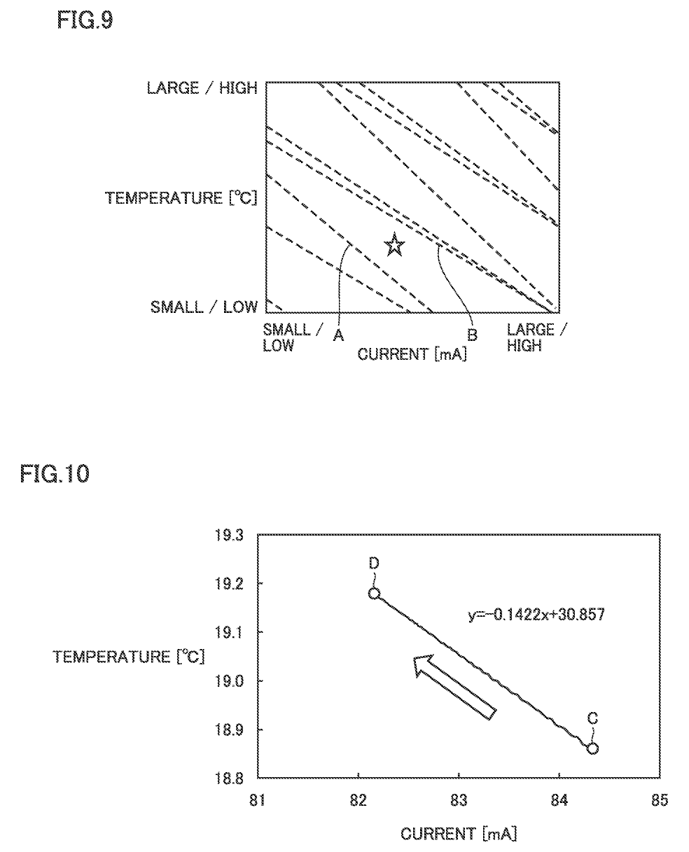

FIG. 9 is a simplified diagram showing the combination of the current flowing through the laser diode and the temperature of the temperature control unit. In FIG. 9, the boundary where a mode hop occurs in FIG. 8 is shown in a simplified manner, and a plurality of straight lines are extracted. The plurality of straight lines are a plurality of linear functions approximately calculated based on the rate of change of temperature with respect to current. The control device 150 calculates, for example, two straight lines such as lines A and B, within which a predetermined target frequency falls. The calculation of the two straight lines may be done by any method, but for example, a wide range may be selected where the target frequency is included and which is enclosed by the two straight lines.

Then, the control device 150 may set the initial value of the parameter combination in the range enclosed by the two straight lines, line A and line B, in FIG. 9. For example, the initial value of the parameter combination is set to the position indicated by the star in FIG. 9. The method for determining the initial value, which is the position of the star, may be any method, but it is preferable to set it at a position far from each of the two straight lines. If the initial position is determined in this way, the initial value will not be set near the boundary where a mode hop occurs, making it possible to avoid the occurrence of a mode hop. In this way, the control device 150 sets the initial value of the parameter combination based on the first data stored in the memory 152 and a predetermined target frequency.

The set initial value of the parameter combination is stored in the memory 152 of the laser device 10. The setting of the initial value of the parameter combination is similarly set for each of the laser devices 10 used in the atomic clock device 100. Thereafter, each of the plurality of laser devices 10 for which the initial value has been adjusted is incorporated into the atomic clock device 100. Each of the plurality of laser devices 10 incorporated into the atomic clock device 100 has individual differences in its resonance structure, but since the initial value is adjusted for each, the accuracy of the atomic clock device 100 is enhanced.

Here, when adjusting the current and temperature in the region enclosed by the two straight lines (the region enclosed by the two linear functions), the parameter combination may be changed as shown in FIG. 10. FIG. 10 is a diagram for explaining a case where the current flowing through the laser diode 30 and the temperature of the temperature control unit 70 are changed in the range from point C to point D. When adjusting the current and temperature in the region enclosed by the two linear functions, if the adjustment is made in the range from point C to point D where no mode hop occurs, a linear function as shown in FIG. 10 is obtained.

The slope of such a linear function may be set within the range of the minimum and maximum slopes of two adjacent linear functions among the plurality of linear functions, or the average value of the slopes may be set. In other words, any method for determining the slope may be used as long as the slope is set within an adjustment range where no mode hop occurs.

Next, the temporal change of the parameter combination will be described. FIG. 11 is a diagram showing the change in current and the change in temperature of the temperature control unit 70 with respect to time in the laser device 10. M1 in FIG. 11 shows the change in temperature with respect to time when adjusted in the range from point C to point D in FIG. 10, and M2 in FIG. 11 shows the change in current with respect to time when adjusted in the range from point C to point D in FIG. 10. As shown in FIG. 11, when adjusted in the range from point C to point D, there is a relationship such that the current decreases as the temperature increases. The difference between the oscillation frequency and the target frequency when adjusted in this way will be described.

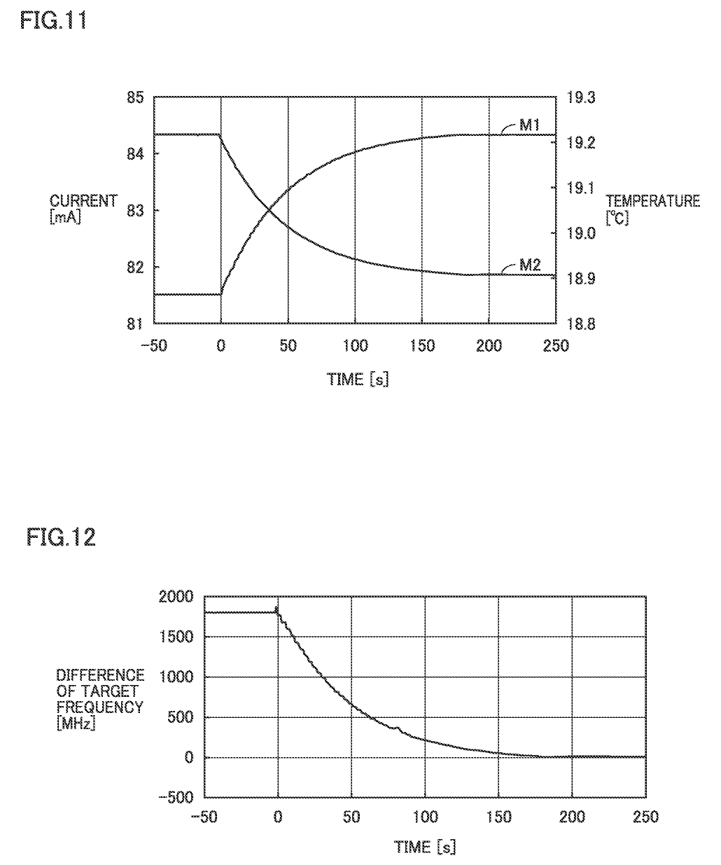

FIG. 12 is a diagram showing the change in the difference from the target frequency with respect to time of the laser light. As shown in FIG. 12, it can be seen that when the parameter combination is adjusted in the range from point C to point D with the setting of FIG. 11, the difference between the oscillation frequency of the laser light and the target frequency approaches 0 over time. In other words, in the laser system 200, by adjusting the current adjustment device 21 and the temperature adjustment device 22 in a range where no mode hop occurs, it is possible to adjust the oscillation frequency in a range where no mode hop occurs.

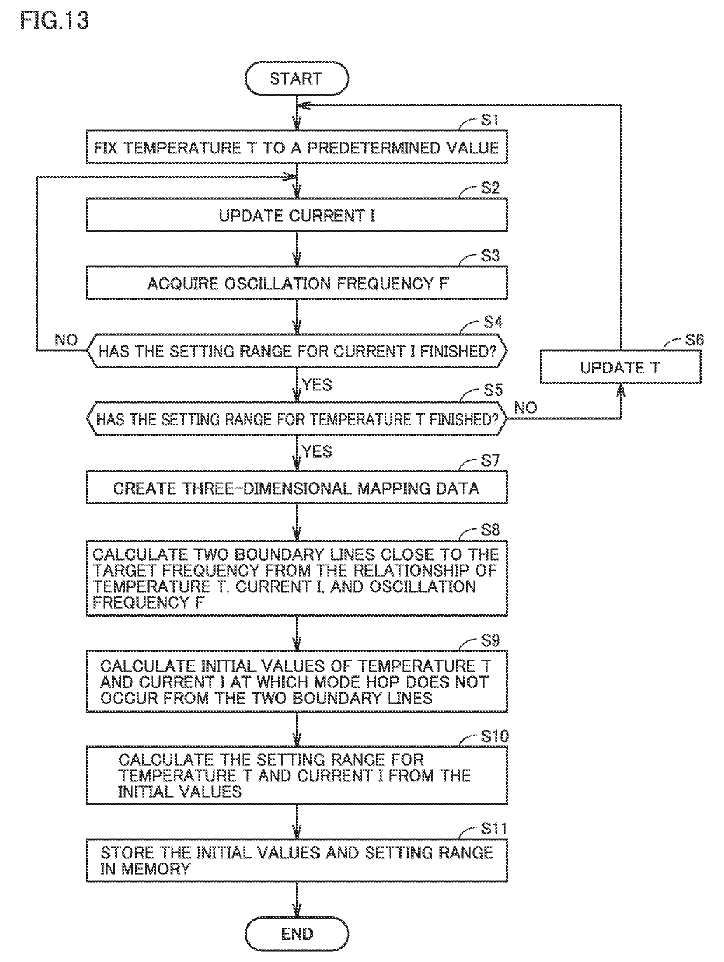

Next, the control content in the laser system 200 according to Embodiment 1 will be described. FIG. 13 is a flowchart showing the control content in the laser system 200. Hereinafter, each step in the flowchart will be simply referred to as "S".

The control device 150 first controls the temperature adjustment device 22 to fix the temperature T of the temperature control unit 70 at a predetermined value (S1). Next, the control device 150 controls the current adjustment device 21 to update the current I flowing through the laser diode 30 (S2). Next, the control device 150 receives a signal related to the oscillation frequency of the laser light from the laser device 10 from the photosensor 12, and stores the oscillation frequency at the time of S1 and S2 in the memory 152 (S3).

Next, the control device 150 determines whether the setting range of the current I has been completed (S4). The setting range of the current I is preset in a range from a lower limit value to an upper limit value. When the control device 150 determines that the setting range of the current I has been completed (YES in S4), the process proceeds to S5. When the control device 150 determines in S4 that the setting range of the current I has not been completed (NO in S4), the process proceeds to S2, and the current I is updated.

In S5, the control device 150 determines whether the setting range of the temperature T has been completed (S5). The setting range of the temperature T is preset in a range from a lower limit value to an upper limit value. When the control device 150 determines that the setting range of the temperature T has been completed (YES in S5), the process proceeds to S7. When the control device 150 determines in S5 that the setting range of the temperature T has not been completed (NO in S5), the temperature T is updated (S6), and the process proceeds to S1.

In S7, the control device 150 creates a two-dimensional table extracted in a matrix by setting a maximum and a minimum for the parameter related to current and the parameter related to temperature, and by associating the measured value of the oscillation frequency for each parameter combination with the two-dimensional table, creates three-dimensional mapping data.

Next, the control device 150 calculates two boundary lines close to the target frequency from the relationship between the temperature T, the current I, and the oscillation frequency F (S8). The processing of S8 is the processing of finding two approximate boundary lines close to the target frequency as described in FIG. 9. Next, in S9, the control device 150 calculates the initial values of the temperature T and the current I at which no mode hop occurs from the two boundary lines calculated in S8.

Next, the control device 150 calculates the setting range of the temperature T and the current I from the initial values (S10). The processing of S10 is the processing of finding a linear function in a range where no mode hop occurs as shown in FIG. 10. Next, the control device 150 stores the initial values obtained in S8 and the setting range obtained in S10 in the memory 152 (S11), and ends the processing.

In this way, the control device 150 can easily adjust the oscillation frequency of the laser light in a range where no mode hop occurs by using the initial value and the setting range of the parameter combination stored in the memory 152.

### Modification

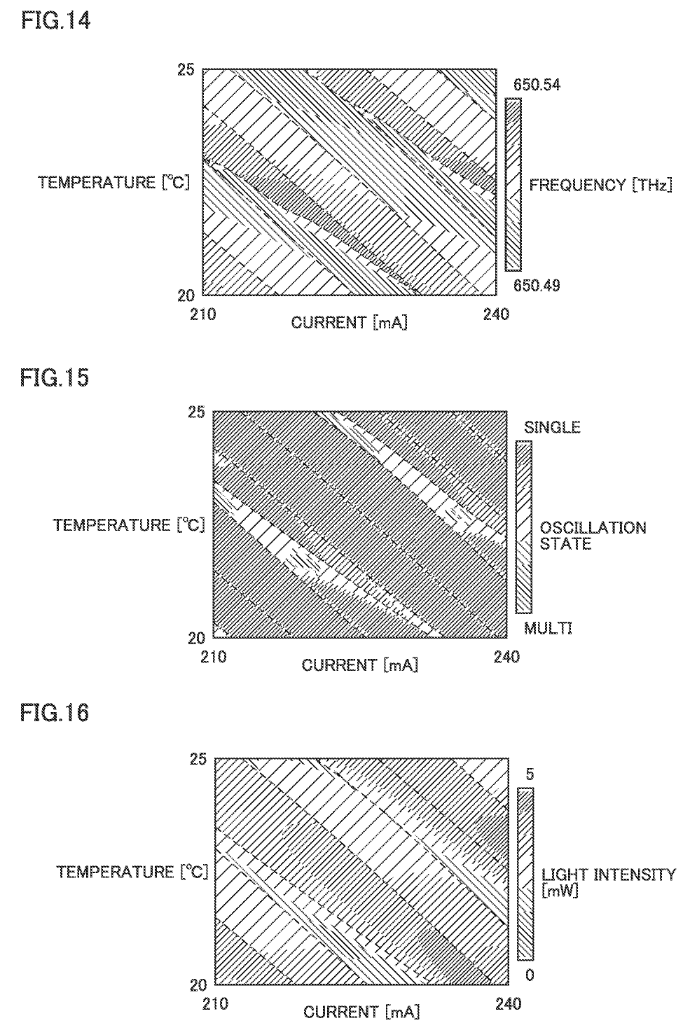

Next, a modification of Embodiment 1 will be described. FIG. 14 is a diagram showing the relationship between the combination of the current flowing through the laser diode 30 and the temperature of the temperature control unit 70, and the frequency of the laser light, according to a modification. In FIG. 14, the current and temperature are set in a different range from Embodiment 1. As shown in FIG. 14, it can be seen that when the current and temperature are different, the position of the broken line, which is the position of the mode hop boundary line, is also different.

FIG. 15 is a diagram showing the relationship between the combination of the current flowing through the laser diode 30 and the temperature of the temperature control unit 70, and the oscillation state of the laser light, according to a modification. The laser light includes a single mode in which only laser light of a specific single wavelength oscillates and a multi-mode in which laser light of each of a plurality of wavelengths oscillates. In the laser device 10, a single-mode oscillation state is more desirable than a multi-mode oscillation state. Such an oscillation state may be used as one index of the parameter combination for setting the initial value.

FIG. 16 is a diagram showing the relationship between the combination of the current flowing through the laser diode 30 and the temperature of the temperature control unit 70, and the light intensity of the laser light, according to a modification. Light intensity is the energy per unit area. In the laser device 10, a higher light intensity is more desirable than a lower light intensity. Such a light intensity may be used as one index of the parameter combination for setting the initial value.

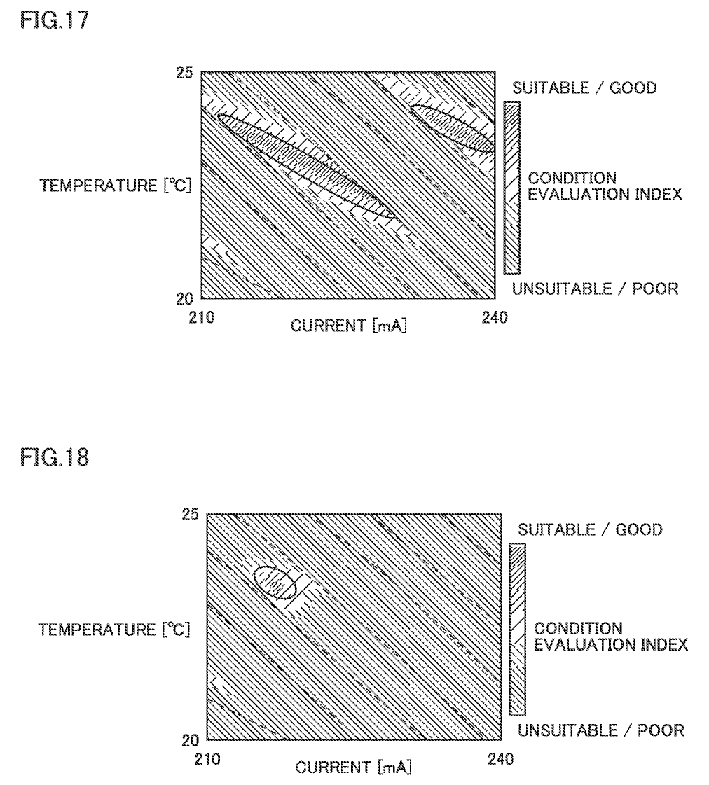

FIG. 17 is a diagram showing the relationship between the combination of the current flowing through the laser diode 30 and the temperature of the temperature control unit 70, and a condition evaluation index, according to a modification. In FIG. 17, the relationship when the oscillation frequency of FIG. 14 and the index of the oscillation state of FIG. 15 are multiplied is shown. In FIG. 17, for example, it can be seen that the regions indicated by the two ellipses are suitable as the condition evaluation index. Therefore, the initial value may be set from the regions indicated by the two ellipses as the initial value of the parameter combination.

FIG. 18 is a diagram showing the relationship between the combination of the current flowing through the laser diode 30 and the temperature of the temperature control unit 70, and a condition evaluation index, according to a modification. In FIG. 18, the relationship when the index of the light intensity of FIG. 16 is further multiplied to FIG. 17 is shown. In FIG. 18, for example, it can be seen that the region indicated by one ellipse is suitable as the condition evaluation index. Therefore, the initial value may be set from the region indicated by one ellipse where the index is maximum as the parameter combination. In this way, by multiplying a plurality of indices, the calculation of the initial value becomes easy.

### Embodiment 2

A laser device 300A of Embodiment 2 will be described. FIG. 19 is a schematic diagram for explaining the laser device 300A according to Embodiment 2. The laser device 300A includes a laser diode 30, lenses 41, 42, 43, a wavelength selection filter 52, a partial reflection mirror 53, and a moving mechanism 71. The configuration of the laser diode 30 is the same as in Embodiment 1.

The ECDL of the laser device 300A changes the distance between the laser diode 30 and the partial reflection mirror 53 by a moving mechanism 71 (not shown). The moving mechanism 71 is, for example, a mechanism that is driven by the flow of current, such as a motor. Note that instead of the moving mechanism 71, it may be configured with a temperature control unit 70 and a mounting part 60 similar to Embodiment 1, or may be configured with a piezoelectric element, which is a piezo element.

### Embodiment 3

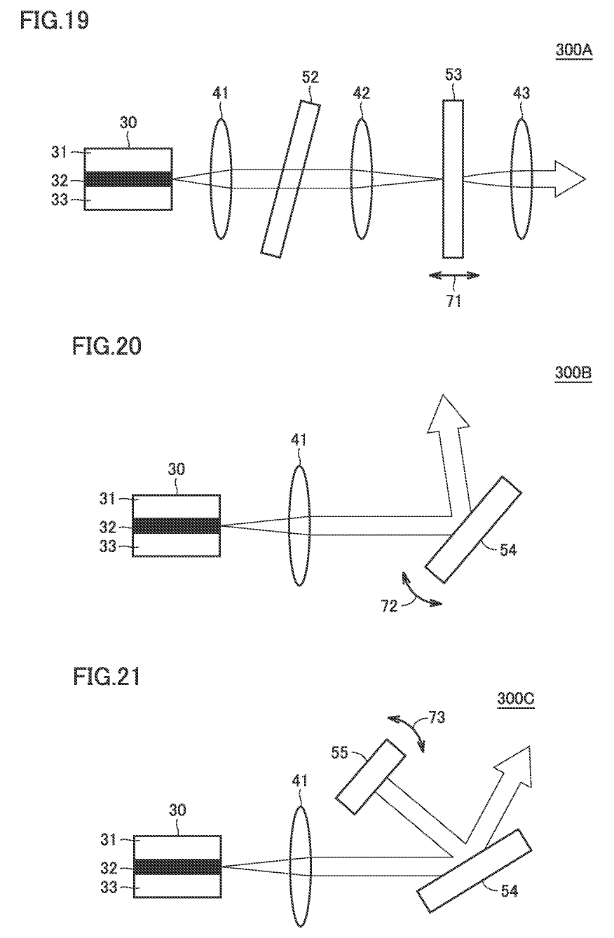

A laser device 300B of Embodiment 3 will be described. FIG. 20 is a schematic diagram for explaining the laser device 300B according to Embodiment 3. The laser device 300B includes a laser diode 30, a lens 41, a diffraction grating 54, and a rotation mechanism 72. The configuration of the laser diode 30 is the same as in Embodiment 1.

The ECDL of the laser device 300B changes the distance between the laser diode 30 and the diffraction grating 54 by a rotation mechanism 72 (not shown). The rotation mechanism 72 is preferably a drive mechanism such as a motor.

### Embodiment 4

A laser device 300C of Embodiment 4 will be described. FIG. 21 is a schematic diagram for explaining the laser device 300C according to Embodiment 4. The laser device 300C includes a laser diode 30, a lens 41, a diffraction grating 54, a mirror 55, and a rotation mechanism 73. The configuration of the laser diode 30 is the same as in Embodiment 1.

The ECDL of the laser device 300C changes the distance between the laser diode 30 and the diffraction grating 54 by changing the position of the mirror 55 by a rotation mechanism 73 (not shown). The laser device 300C has a structure in which the diffraction grating is fixed, unlike the laser device 300B of Embodiment 3. In this embodiment, in addition to parameters such as the distance between optical elements, the diffraction grating angle and the mirror angle are newly included as parameters constituting the optical system.

### Aspects

Those skilled in the art will understand that the exemplary embodiments described above are specific examples of the following aspects.

(Item 1) An atomic clock device according to one aspect comprises a vacuum chamber, an atom generating device that irradiates an atomic beam into the vacuum chamber, a laser device that excites a transition between energy levels of atoms by irradiating laser light into the vacuum chamber in a state where the atomic beam is irradiated from the atom generating device, and a control device that controls the laser device. The laser device comprises an optical system including a laser diode that emits laser light and an external resonator provided outside the laser diode that resonates the laser light emitted from the laser diode. The oscillation frequency of the laser light from the laser device changes based on the current flowing through the laser diode and the optical system including the laser diode and the external resonator. An initial value of a parameter combination is set based on first data indicating a change in the oscillation frequency with respect to the parameter combination of a first parameter for adjusting the current and a second parameter for adjusting the optical system, and a predetermined target frequency.

According to the atomic clock device described in Item 1, since the initial value of the parameter combination is set based on the first data indicating the change in the oscillation frequency with respect to the parameter combination of the first parameter for adjusting the current flowing through the laser diode and the second parameter for adjusting the optical system including the laser diode and the external resonator, and a predetermined target frequency, the oscillation frequency of the laser light emitted from the laser device can be appropriately adjusted.

(Item 2) In the atomic clock device described in Item 1, the first data is acquired by a preliminary analysis that scans the first parameter and the second parameter.

According to the atomic clock device described in Item 2, the first data can be acquired by a preliminary analysis that scans the first parameter and the second parameter.

(Item 3) In the atomic clock device described in Item 1 or 2, a range in which the parameter combination can be set includes an adjustment range in which a mode hop, where the oscillation frequency changes, does not occur. The initial value of the parameter combination is selected from a plurality of parameter combinations included in the adjustment range.

According to the atomic clock device described in Item 3, the initial value of the parameter combination can be set in an adjustment range in which a mode hop, where the oscillation frequency changes, does not occur.

(Item 4) In the atomic clock device described in Item 3, a plurality of linear functions are calculated based on the first data. The adjustment range is defined based on the plurality of linear functions.

According to the atomic clock device described in Item 4, the adjustment range can be determined from a plurality of linear functions.

(Item 5) In the atomic clock device described in any one of Items 1 to 4, an oscillation state of the laser light from the laser device includes a single mode in which only laser light of a specific wavelength oscillates and a multi-mode in which laser light of each of a plurality of wavelengths oscillates. The initial value is further set based on the oscillation state of the laser light.

According to the atomic clock device described in Item 5, the initial value can be set based on the oscillation state of the laser light.

(Item 6) In the atomic clock device described in any one of Items 1 to 5, the initial value is further set based on the light intensity of the laser light.

According to the atomic clock device described in Item 6, the initial value can be set based on the light intensity of the laser light.

(Item 7) In the atomic clock device described in any one of Items 1 to 6, the laser device further comprises a temperature element that adjusts the optical system by applying heat to a mounting part on which the external resonator is mounted. The second parameter includes a temperature of the temperature element.

According to the atomic clock device described in Item 7, the optical system including the laser diode and the external resonator can be adjusted by the change in the temperature of the temperature element.

(Item 8) In the atomic clock device described in any one of Items 1 to 7, the laser device further comprises a piezoelectric element that adjusts the optical system by expanding and contracting based on a voltage. The second parameter includes a voltage of the piezoelectric element.

According to the atomic clock device described in Item 8, the optical system including the laser diode and the external resonator can be adjusted by the change in the voltage of the piezoelectric element.

(Item 9) In the atomic clock device described in any one of Items 1 to 8, the laser device further comprises a moving mechanism that changes a position of the external resonator. The second parameter includes a current of the moving mechanism.

According to the atomic clock device described in Item 9, the distance between the laser diode and the external resonator can be adjusted by a motor.

(Item 10) A laser system according to one aspect relates to a laser system for adjusting an oscillation frequency of laser light emitted from a laser device. The laser system comprises the laser device and a control device that controls the laser device. The laser device comprises an optical system including a laser diode that emits laser light and an external resonator provided outside the laser diode that resonates the laser light emitted from the laser diode. The oscillation frequency of the laser light from the laser device changes based on the current flowing through the laser diode and the optical system including the laser diode and the external resonator. The control device includes a step of acquiring first data indicating a change in the oscillation frequency with respect to a parameter combination of a first parameter for adjusting the current and a second parameter for adjusting the optical system, and a step of setting an initial value of the parameter combination based on the first data and a predetermined target frequency.

According to the laser system described in Item 10, since the initial value of the parameter combination is set based on the first data indicating the change in the oscillation frequency with respect to the parameter combination of the first parameter for adjusting the current flowing through the laser diode and the second parameter for adjusting the optical system including the laser diode and the external resonator, and a predetermined target frequency, the oscillation frequency of the laser light emitted from the laser device can be appropriately adjusted.

(Item 11) An adjustment method according to one aspect relates to an adjustment method for adjusting an oscillation frequency of laser light from a laser device by a computer. The laser device comprises an optical system including a laser diode that emits laser light and an external resonator provided outside the laser diode that resonates the laser light emitted from the laser diode. The oscillation frequency of the laser light from the laser device changes based on the current flowing through the laser diode and the optical system including the laser diode and the external resonator. Processing executed by the computer includes a step of acquiring first data indicating a change in the oscillation frequency with respect to a parameter combination of a first parameter for adjusting the current and a second parameter for adjusting the optical system, and a step of setting an initial value of the parameter combination based on the first data and a predetermined target frequency.

According to the adjustment method described in Item 11, since the initial value of the parameter combination is set based on the first data indicating the change in the oscillation frequency with respect to the parameter combination of the first parameter for adjusting the current flowing through the laser diode and the second parameter for adjusting the optical system including the laser diode and the external resonator, and a predetermined target frequency, the oscillation frequency of the laser light emitted from the laser device can be appropriately adjusted.

The embodiments disclosed this time should be considered as illustrative in all respects and not restrictive. The scope of the present disclosure is indicated by the scope of the claims rather than the description of the embodiments described above, and it is intended that all modifications within the meaning and scope equivalent to the scope of the claims are included.

### REFERENCE SIGNS LIST

10, 300A, 300B, 300C Laser device, 10A Cooling laser device, 10B Excitation laser device, 10C Detection laser device, 10D Optical lattice laser device, 11 Splitter, 12 Photosensor, 21 Current adjustment device, 22 Temperature adjustment device, 30 Laser diode, 31 P-type clad layer, 32 Active layer, 33 N-type clad layer, 36 Pedestal part, 40 Lens unit, 41, 42, 43 Lens, 50 External resonator, 51 Pedestal part, 52 Wavelength selection filter, 53 Partial reflection mirror, 54 Diffraction grating, 55, 131, 132 Mirror, 60 Mounting part, 70 Temperature control unit, 71 Moving mechanism, 72, 73 Rotation mechanism, 100 Atomic clock device, 110 Atom generating device, 130 Vacuum chamber, 140 Detection device, 150, 170 Control device, 152, 172 Memory, 160 Magnetic field generating device, 190 Optical lattice, 200 Laser system.

1. An atomic clock device, comprising:
a vacuum chamber;
an atom generating device that irradiates an atomic beam into the vacuum chamber;
a laser device that excites a transition between energy levels of atoms by irradiating laser light into the vacuum chamber in a state where the atomic beam is irradiated from the atom generating device; and
a control device that controls the laser device,
wherein the laser device comprises an optical system including a laser diode that emits laser light and an external resonator provided outside the laser diode that resonates the laser light emitted from the laser diode,
the oscillation frequency of the laser light from the laser device changes based on the current flowing through the laser diode and the optical system including the laser diode and the external resonator, and
an initial value of a parameter combination is set based on first data indicating a change in the oscillation frequency with respect to the parameter combination of a first parameter for adjusting the current and a second parameter for adjusting the optical system, and a predetermined target frequency.

2. The atomic clock device according to claim 1, wherein the first data is acquired by a preliminary analysis that scans the first parameter and the second parameter.

3. The atomic clock device according to claim 1, wherein a range in which the parameter combination can be set includes an adjustment range in which a mode hop, where the oscillation frequency changes, does not occur, and
the initial value of the parameter combination is selected from a plurality of parameter combinations included in the adjustment range.

4. The atomic clock device according to claim 3, wherein a plurality of linear functions are calculated based on the first data, and
the adjustment range is defined based on the plurality of linear functions.

5. The atomic clock device according to claim 1, wherein an oscillation state of the laser light from the laser device includes a single mode in which only laser light of a specific wavelength oscillates and a multi-mode in which laser light of each of a plurality of wavelengths oscillates, and
the initial value is further set based on the oscillation state of the laser light.

6. The atomic clock device according to claim 1, wherein the initial value is further set based on the light intensity of the laser light.

7. The atomic clock device according to claim 1, wherein the laser device further comprises a temperature element that adjusts the optical system by applying heat to a mounting part on which the external resonator is mounted, and
the second parameter includes a temperature of the temperature element.

8. The atomic clock device according to claim 1, wherein the laser device further comprises a piezoelectric element that adjusts the optical system by expanding and contracting based on a voltage, and
the second parameter includes a voltage of the piezoelectric element.

9. The atomic clock device according to claim 1, wherein the laser device further comprises a moving mechanism that changes a position of the external resonator, and
the second parameter includes a current of the moving mechanism.

10. A laser system for adjusting an oscillation frequency of laser light emitted from a laser device, comprising:
the laser device; and
a control device that controls the laser device,
wherein the laser device comprises an optical system including a laser diode that emits laser light and an external resonator provided outside the laser diode that resonates the laser light emitted from the laser diode,
the oscillation frequency of the laser light from the laser device changes based on the current flowing through the laser diode and the optical system including the laser diode and the external resonator, and
the control device includes:
a step of acquiring first data indicating a change in the oscillation frequency with respect to a parameter combination of a first parameter for adjusting the current and a second parameter for adjusting the optical system; and
a step of setting an initial value of the parameter combination based on the first data and a predetermined target frequency.

11. An adjustment method for adjusting an oscillation frequency of laser light from a laser device by a computer,
wherein the laser device comprises an optical system including a laser diode that emits laser light and an external resonator provided outside the laser diode that resonates the laser light emitted from the laser diode,
the oscillation frequency of the laser light from the laser device changes based on the current flowing through the laser diode and the optical system including the laser diode and the external resonator, and
the processing executed by the computer comprises:
a step of acquiring first data indicating a change in the oscillation frequency with respect to a parameter combination of a first parameter for adjusting the current and a second parameter for adjusting the optical system; and
a step of setting an initial value of the parameter combination based on the first data and a predetermined target frequency.
